(19) United States
(12) Patent Application Publication
(10) Pub. No.: US 2026/0090056 A1
(43) Pub. Date: Mar. 26, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kazuki MINAMIKAWA, Nomi Ishikawa (JP); Akiyo MINAMIKAWA, Nomi Ishikawa (JP); Hidenobu KOJIMA, Kanazawa Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/064,880

(22) Filed: Feb. 27, 2025

(30) Foreign Application Priority Data
Sep. 24, 2024 (JP) 2024-164811

(51) Int. Cl. H10D 64/23; H10D 12/00

(52) U.S. Cl. CPC H10D 64/232; H10D 12/461

(57) ABSTRACT

A semiconductor device according to an embodiment includes: a collector electrode, a semiconductor portion disposed on the collector electrode, a plurality of emitter electrodes disposed on a part of the semiconductor portion and spaced apart from each other in a first direction, a gate wiring disposed between the emitter electrodes in the first direction, a gate electrode connected to the gate wiring and insulated from the semiconductor portion, having two first portions extending in the first direction and a second portion connecting the ends of the two first portions, arranged in a second direction intersecting the first direction, an emitter contact with an upper end connected to the emitter electrode and a lower end connected to a portion between the region directly below the gate wiring and the second portion in the semiconductor portion.

### CROSS-REFERENCE TO RELATED APPLICATION

This application is based upon and claims the benefit of priority from Japanese Patent Application No. 2024-164811, filed on Sep. 24, 2024, the entire contents of which are incorporated herein by reference.

### FIELD

Embodiments described herein relate generally to a semiconductor device.

### BACKGROUND

As a type of semiconductor device for power control, the IGBT (Insulated Gate Bipolar Transistor) has been developed. In IGBTs, there is a desire to improve the blocking capability, which is a type of breakdown resistance during turn-off.

### BRIEF DESCRIPTION OF THE DRAWINGS

FIG. 1 is a top view showing the IGBT according to the first embodiment.

FIG. 2 is a partially enlarged top view showing region A of FIG. 1.

FIG. 3 is a cross-sectional view along line B-B′ of FIG. 2.

FIG. 4 is a cross-sectional view along line C-C′ of FIG. 2.

FIG. 5 is a cross-sectional view showing the operation of the IGBT according to the first embodiment.

FIG. 6 is a plan view showing the IGBT according to a comparative example.

FIG. 7 is a plan view showing the IGBT according to the second embodiment.

FIG. 8 is a plan view showing the IGBT according to the third embodiment.

### DETAILED DESCRIPTION

A semiconductor device according to an embodiment includes: a collector electrode, a semiconductor portion disposed on the collector electrode, a plurality of emitter electrodes disposed on a part of the semiconductor portion and spaced apart from each other in a first direction, a gate wiring disposed between the emitter electrodes in the first direction, a gate electrode connected to the gate wiring and insulated from the semiconductor portion, having two first portions extending in the first direction and a second portion connecting the ends of the two first portions, arranged in a second direction intersecting the first direction, an emitter contact with an upper end connected to the emitter electrode and a lower end connected to a portion between the region directly below the gate wiring and the second portion in the semiconductor portion.

Hereinafter, embodiments of the present disclosure will be described with reference to the drawings. In the following description, the same or similar members and the like are denoted by the same reference numerals, and the description of the members and the like once described shall be appropriately omitted.

In the present specification, when there are notations of n⁺ type, n type, and n⁻ type, it means that an n type impurity concentration decreases in the order of n⁺ type, n type, and n⁻ type. In addition, when there are notations of p⁺ type, p type, and p⁻ type, it means that the p type impurity concentration decreases in the order of p⁺ type, p type, and p⁻ type.

Qualitative analyses and quantitative analyses of chemical compositions of members constituting the semiconductor device in the present specification can be performed by, for example, secondary ion mass spectrometry (SIMS), energy dispersive X-ray spectroscopy (EDX), and Rutherford backscattering spectrometry (Rutherford BackScattering Spectroscopy: RBS). In addition, for example, a transmission electron microscope (TEM) can be used for measuring thicknesses of the members constituting the semiconductor device, distances between the members, and the like.

### First Embodiment

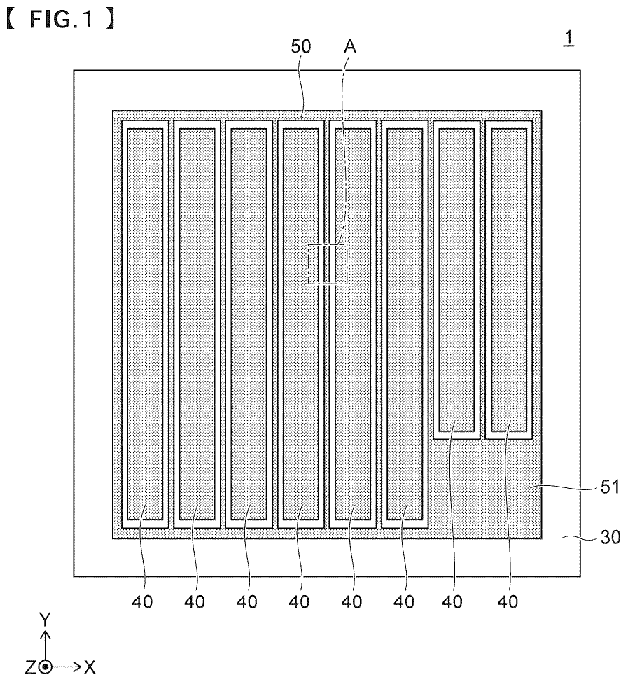

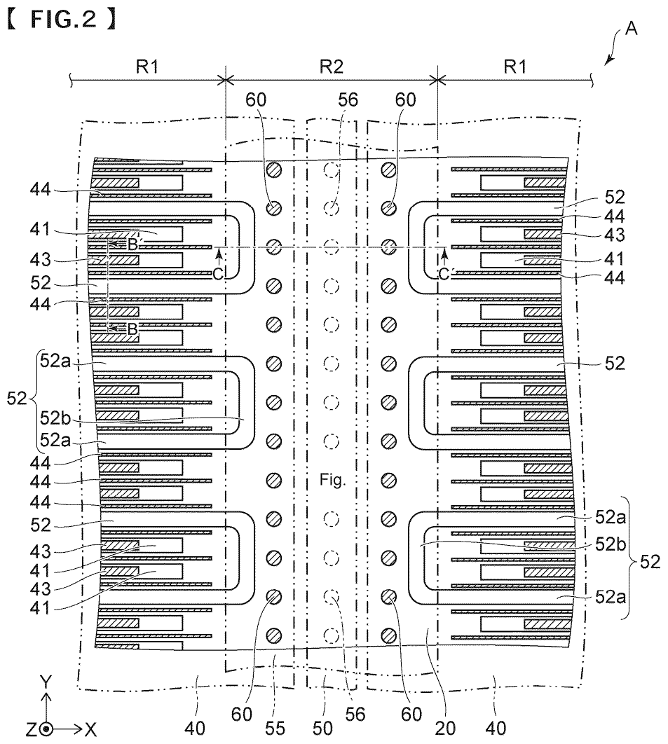

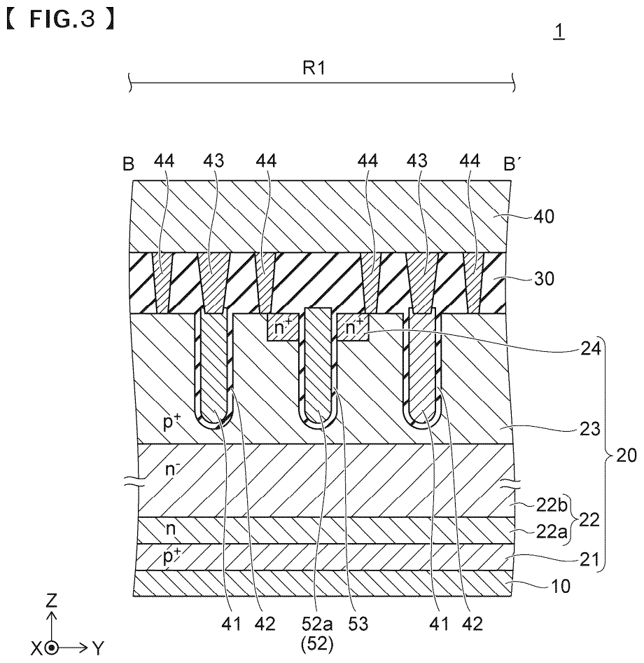

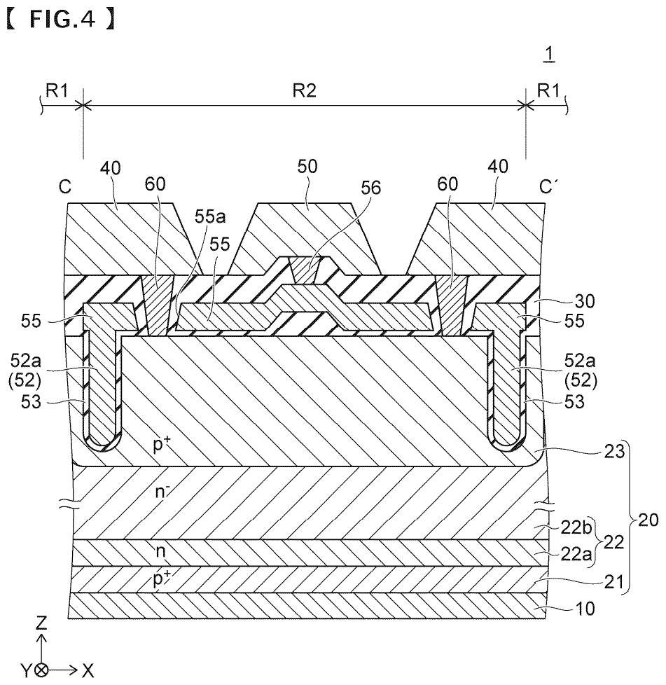

FIG. 1 is a top view showing the IGBT according to the present embodiment. FIG. 2 is a partially enlarged top view showing region A of FIG. 1. FIG. 3 is a cross-sectional view along line B-B′ of FIG. 2. FIG. 4 is a cross-sectional view along line C-C′ of FIG. 2. Note that each figure is schematic and appropriately emphasized or simplified. For example, in FIG. 2, the insulating parts are omitted. The same applies to other figures described later.

The collector electrode 10 is disposed over the entire lower surface of the semiconductor portion 20 and is in contact with the semiconductor portion 20. The insulating film 30 is disposed over the entire upper surface of the semiconductor portion 20. The plurality of emitter electrodes 40 are disposed on a part of the insulating film 30 and are spaced apart from each other. The gate wiring 50 is disposed on a part of the insulating film 30 where the emitter electrodes 40 are not disposed.

As shown in FIG. 1, the emitter electrodes 40 are disposed in the cell region excluding the terminal region of the IGBT 1 and are arranged, for example, in one direction. Hereinafter, for convenience of explanation, an XYZ orthogonal coordinate system is adopted. The direction from the collector electrode 10 to the emitter electrodes 40 is referred to as the “Z direction,” the direction in which the plurality of emitter electrodes 40 are arranged is referred to as the “X direction,” and the direction orthogonal to both the Z direction and the X direction is referred to as the “Y direction.” The Z direction is also referred to as “up,” and the opposite direction is referred to as “down,” but this expression is also for convenience and is unrelated to the direction of gravity.

When viewed from the Z direction, the shape of each emitter electrode 40 is a rectangle with a length in the Y direction longer than the length in the X direction. When viewed from the Z direction, the shape of the gate wiring 50 is, for example, ladder-shaped, surrounding each emitter electrode 40. Note that the emitter electrodes 40 may be arranged in a matrix along both the X direction and the Y direction. In this case, when viewed from the Z direction, the shape of the gate wiring 50 may be grid-shaped, surrounding each emitter electrode 40. The gate wiring 50 is provided with a gate pad 51 at the corner of the cell region.

As shown in FIG. 2, in the cell region of the IGBT 1, the region directly below the central part in the X direction of the emitter electrodes 40 is referred to as the “current conduction region R1.” In the current conduction region R1, current can flow from the collector electrode 10 to the emitter electrodes 40 through the semiconductor portion 20. In the cell region, the region directly below the gate wiring 50 and the region directly below the vicinity of the gate wiring 50 in the emitter electrodes 40 are referred to as the “gate connection region R2.” In the gate connection region R2, a gate electrode 52, described later, is connected to the gate wiring 50. Note that “connection” in this specification means electrical connection. In the cell region, the current conduction region R1 and the gate connection region R2 are alternately arranged along the X direction.

The gate electrode 52 is disposed across the current conduction region R1 and the gate connection region R2. When viewed from the Z direction, the shape of the gate electrode 52 is loop-shaped. That is, the gate electrode 52 is mainly disposed in the current conduction region R1 and includes two first portions 52a extending in the X direction and a second portion 52b disposed in the gate connection region R2 and extending in the Y direction, connecting the tips of the two first portions 52a on the gate connection region R2 side.

As shown in FIGS. 2 and 3, in the current conduction region R1, trench electrodes 41, trench insulating films 42, the first portions 52a of the gate electrode 52, and gate insulating films 53 are provided in the semiconductor portion 20. Emitter plugs 43 and emitter plugs 44 are provided in the insulating film 30. The gate insulating film 53 is disposed around the gate electrode 52, insulating the gate electrode 52 from the semiconductor portion 20. The emitter electrodes 40 are connected to the trench electrodes 41 through the emitter plugs 43. The emitter electrodes 40 are also connected to the semiconductor portion 20 through the emitter plugs 44.

A plurality of trench electrodes 41 are provided and arranged along the Y direction. Each trench electrode 41 extends in the X direction. The trench insulating film 42 is disposed around the trench electrodes 41, insulating the trench electrodes 41 from the semiconductor portion 20. The first portions 52a of the gate electrode 52 are arranged to interpose the arrangement of the trench electrodes 41, (first portion).

The trench electrodes 41 are disposed inside the loop of the gate electrode 52 and between two adjacent gate electrodes 52 in the Y direction. In the example shown in FIG. 2, two trench electrodes 41 are disposed inside the loop of the gate electrode 52, and two trench electrodes 41 are disposed between the two gate electrodes 52, but this is not limited to this. Three or more trench electrodes 41 may be disposed inside the loop of the gate electrode 52 and between the gate electrodes 52, or no trench electrodes 41 may be disposed inside the loop of the gate electrode 52 or between the gate electrodes 52.

As shown in FIGS. 2 and 4, in the gate connection region R2, the second portion 52b of the gate electrode 52 and the gate insulating film 53 are provided in the semiconductor portion 20. An internal gate wiring 55, a gate plug 56, and an emitter contact 60 are provided in the insulating film 30. The gate wiring 50 is connected to the internal gate wiring 55 through the gate plug 56. The internal gate wiring 55 is connected to the second portion 52b of the gate electrode 52.

An opening 55a is formed in the internal gate wiring 55. The emitter contact 60 penetrates the opening 55a of the internal gate wiring 55 in the Z direction. The upper end of the emitter contact 60 is connected to the emitter electrode 40, and the lower end of the emitter contact 60 is connected to the semiconductor portion 20.

As shown in FIG. 2, in the present embodiment, a plurality of emitter contacts 60 are arranged, for example, at equal intervals along the Y direction in the gate connection region R2. The shape of each emitter contact 60 is approximately cylindrical with a central axis extending in the Z direction. The emitter contacts 60 are disposed between two gate electrodes 52 arranged in the X direction and directly below two emitter electrodes 40 spaced apart in the X direction.

Some of the emitter contacts 60 are connected to the portion between the region directly below the gate wiring 50 and the second portion 52b of the gate electrode 52 in the semiconductor portion 20. Other emitter contacts 60 are connected to the portion between the trench electrodes 41 disposed between the gate electrodes 52 in the semiconductor portion 20 and the region directly below the gate wiring 50.

As shown in FIGS. 3 and 4, the semiconductor portion 20 includes a p+type collector layer 21, an n type drift layer 22, a p+ type base layer 23, and an n+ type emitter layer 24. The drift layer 22 includes an n type first layer 22a and an n-type second layer 22b.

The notation “n+” indicates a higher carrier concentration than “n”, and “n−” indicates a lower carrier concentration than “n”. The terms “n+”, “n”, and “n−” are collectively referred to as “n type”. The same applies to p type. “Carrier concentration” refers to the impurity concentration contributing to the conductivity of the semiconductor. When both acceptor and donor impurities are present in a region, the effective concentration is the net concentration after canceling out the opposing contributions.

The collector layer 21 is in contact with and connected to the collector electrode 10. The first layer 22a of the drift layer 22 is disposed on and in contact with the collector layer 21. The second layer 22b of the drift layer 22 is disposed on the first layer 22a. The base layer 23 is disposed on and in contact with the drift layer 22. The emitter layer 24 is disposed on a part of the base layer 23 in the current conduction region R1. The emitter layer 24 is in contact with the gate insulating film 53 and faces the first portion 52a of the gate electrode 52 through the gate insulating film 53. The trench electrodes 41 and trench insulating films 42, as well as the gate electrode 52 and gate insulating film 53, are disposed within the base layer 23.

In the current conduction region R1, the emitter plug 44 is connected to the base layer 23 and the emitter layer 24. In other words, in the current conduction region R1, the base layer 23 and the emitter layer 24 are connected to the emitter electrode 40 through the emitter plug 44. In the gate connection region R2, the emitter contact 60 is connected to the base layer 23. In other words, in the gate connection region R2, the base layer 23 is connected to the emitter electrode 40 through the emitter contact 60. The gate electrode 52 is connected to the gate wiring 50 through the internal gate wiring 55 and the gate plug 56 in the gate connection region R2.

Next, examples of materials for each part will be described. The semiconductor portion 20 includes, for example, single-crystal silicon. The insulating film 30 includes, for example, silicon oxide (SiO2). The internal gate wiring 55 includes, for example, polysilicon. The collector electrode 10, emitter electrodes 40, and gate wiring 50 include, for example, one or more materials selected from the group consisting of aluminum (Al), aluminum-copper alloy (AlCu), aluminum silicide (AlSi), titanium (Ti), and titanium nitride (TiN). The emitter contact 60, emitter plugs 43 and 44, and gate plug 56 include, for example, one or more materials selected from the group consisting of titanium (Ti), titanium nitride (TiN), and tungsten (W).

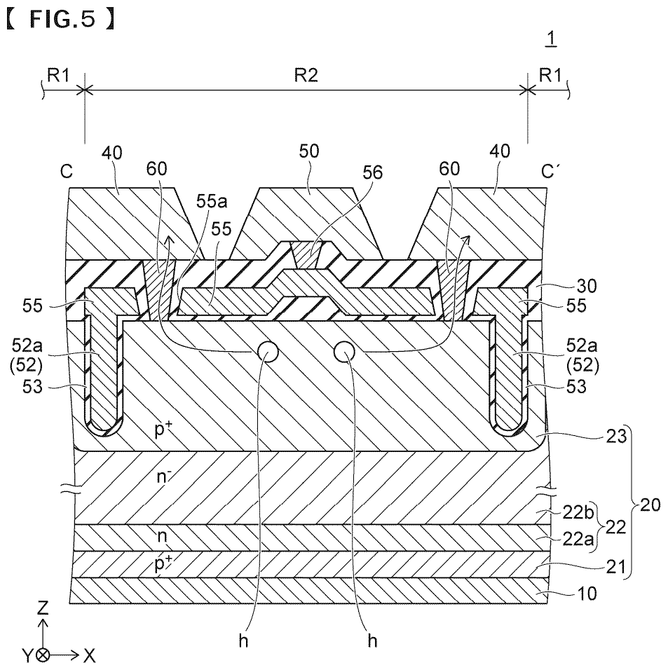

Next, the operation of the IGBT 1 according to the present embodiment will be described. FIG. 5 is a cross-sectional view showing the operation of the IGBT according to the present embodiment. FIG. 5 shows the same cross-section as FIG. 4.

As shown in FIG. 5, when the IGBT 1 is turned off, holes (h), which are carriers, enter the semiconductor portion 20. The holes (h) that have entered the current conduction region R1 move to the emitter electrode 40 through the emitter plug 44 and are discharged outside the IGBT 1. The holes (h) that have entered the gate connection region R2 move to the emitter electrode 40 through the emitter contact 60 and are discharged outside the IGBT 1.

Next, the effects of this embodiment will be described. In this embodiment, the emitter contact 60 is provided outside the loop-shaped gate electrode 52 and the gate insulating film 53 in the gate connection region R2. As a result, the holes (h) in the gate connection region R2 are discharged to the emitter electrode 40 via the emitter contact 60. This makes it difficult for the current to concentrate during turn-off, making the IGBT 1 less likely to be destroyed. Therefore, the IGBT 1 according to this embodiment has a high blocking capacity.

In addition, in the IGBT 1 according to this embodiment, the gate electrode 52 is formed in a loop shape. As a result, the gate withstand voltage is higher compared to the case where the gate electrode 52 is formed in a straight line. That is, it has been experimentally confirmed that when the second portion 52b is provided in the gate electrode 52, the occurrence rate of gate withstand voltage failure is reduced compared to the case where the gate electrode 52 is composed only of the first portion 52a.

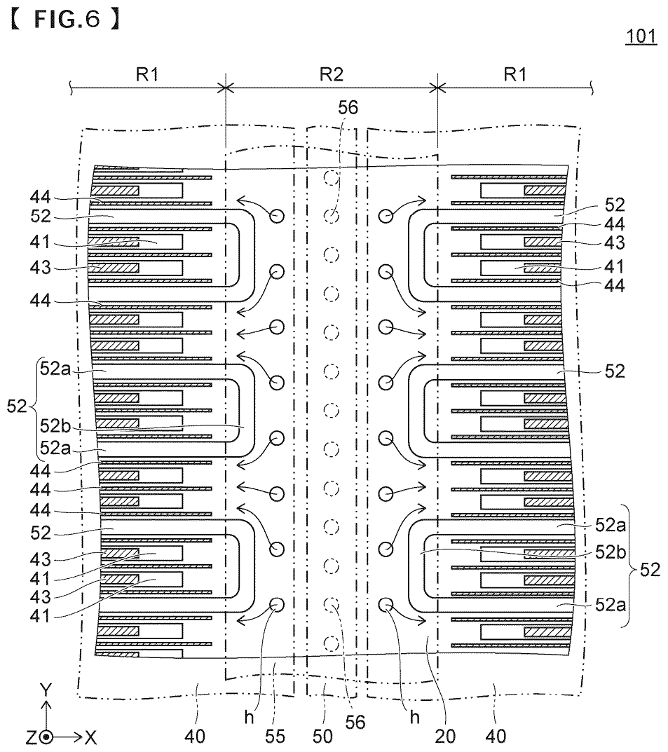

FIG. 6 is a plan view showing an IGBT according to a comparative example. As shown in FIG. 6, in the IGBT 101 according to this comparative example, the emitter contact 60 is not provided. Therefore, when the IGBT 101 is turned off, the holes (h) that have entered the gate connection region R2 need to move to the conduction region R1 and then be discharged to the emitter electrode 40 via the emitter plug 44.

However, since part of the holes (h) that have entered the gate connection region R2 are blocked from moving by the loop-shaped gate electrode 52 and the gate insulating film 53, the movement distance to the emitter plug 44 becomes longer. As a result, the discharge of the holes (h) is suppressed. Consequently, the current concentrates in the portion where the holes (h) remain in the gate connection region R2, increasing the likelihood of the IGBT 101 being destroyed.

### Second Embodiment

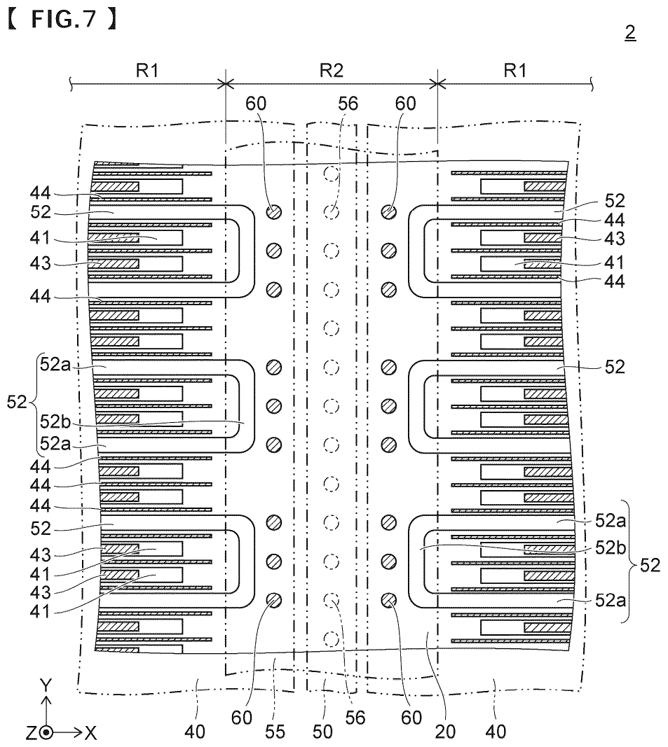

FIG. 7 is a plan view showing an IGBT according to this embodiment. As shown in FIG. 7, in the IGBT 2 according to this embodiment, the arrangement of the emitter contact 60 is different compared to the first embodiment. In the IGBT 2, as viewed from the Z direction, the emitter contact 60 is not arranged between the portions of the gate electrode 52 in the semiconductor portion 20 and the gate wiring 50, but only between the gate electrode 52 and the gate wiring 50 in the semiconductor portion 20. That is, in this embodiment, the lower end of the emitter contact 60 is connected only to the portion between the gate wiring 50 and the second portion 52b of the gate electrode 52 in the semiconductor portion 20.

According to this embodiment, the holes (h) located between the gate wiring 50 and the gate electrode 52 in the semiconductor portion 20 are easily discharged via the emitter contact 60. Also, the holes (h) located between the gate wiring 50 and the gate electrode 52 in the Y direction in the semiconductor portion 20 are easily discharged via the emitter plug 44. This also provides the same effect as the first embodiment. The other configurations, operations, and effects in this embodiment are the same as those in the first embodiment.

### Third Embodiment

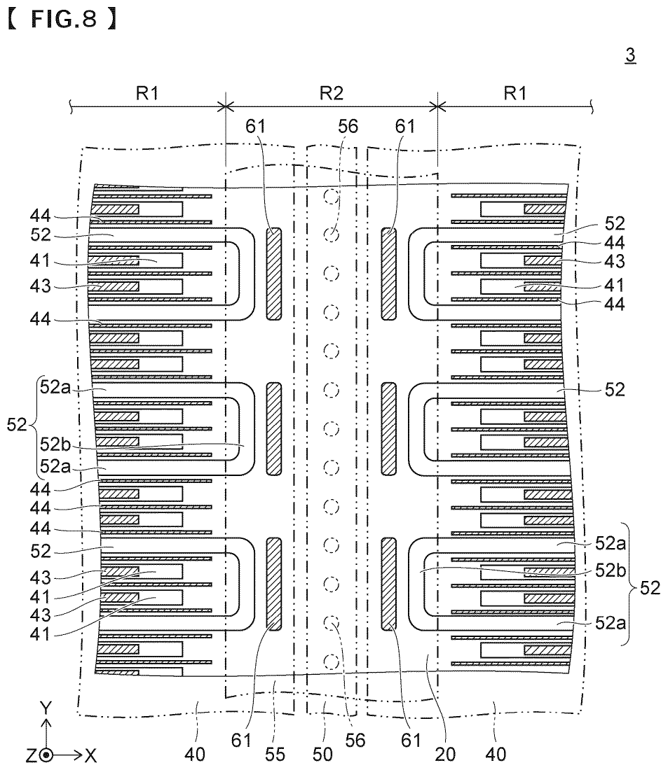

FIG. 8 is a plan view showing an IGBT according to this embodiment. As shown in FIG. 8, in the IGBT 3 according to this embodiment, the shape of the emitter contact 61 is different compared to the first embodiment.

As shown in FIG. 8, in the IGBT 3, the emitter contact 61 is provided. The shape of the emitter contact 61 is a plate shape with a length in the Y direction longer than the length in the X direction. The upper end of the emitter contact 61 is connected to the emitter electrode 40, and the lower end of the emitter contact 61 is connected to the portion between the gate wiring 50 and the second portion 52b of the gate electrode 52 in the semiconductor portion 20. The other configurations, operations, and effects in this embodiment are the same as those in the first embodiment.

According to the embodiments described above, it is possible to realize an IGBT with improved blocking capacity.

Although several embodiments of the present invention have been described above, these embodiments are presented as examples and are not intended to limit the scope of the invention. These novel embodiments can be implemented in various other forms, and various omissions, substitutions, and changes can be made without departing from the gist of the invention. These embodiments and their modifications are included in the scope and gist of the invention, as well as in the scope of the invention described in the claims and their equivalents. Furthermore, the above-described embodiments can be implemented in combination with each other.

For example, in each of the above embodiments, the p-type and n-type may be reversed to form a p-channel IGBT. In this case, the emitter contact functions as a contact for discharging electrons.

The present invention includes the following aspects.

### Explanation of Symbols

1, 2, 3: IGBT 10: Collector electrode
20: Semiconductor portion
21: Collector layer (first semiconductor layer)
22: Drift layer (second semiconductor layer)
22a: First layer 22b: Second layer 23: Base layer (third semiconductor layer)
24: Emitter layer (fourth semiconductor layer)
30: Insulating film
40: Emitter electrode
41: Trench electrode
42: Trench insulating film
43, 44: Emitter plug
50: Gate wiring
51: Gate pad
52: Gate electrode
52a: First portion
52b: Second portion
53: Gate insulating film
55: Internal gate wiring
55a: Opening
56: Gate plug
60: Emitter contact
61: Emitter contact
101: IGBT
R1: Conduction region
R2: Gate connection region
h: Hole

What is claimed is:

1. A semiconductor device comprising:
a collector electrode;
a semiconductor portion disposed on the collector electrode;
a plurality of emitter electrodes disposed on a part of the semiconductor portion and spaced apart from each other in a first direction;
a gate wiring disposed between the emitter electrodes in the first direction;
a gate electrode connected to the gate wiring and insulated from the semiconductor portion, having two first portions extending in the first direction and a second portion connecting the ends of the two first portions, arranged in a second direction intersecting the first direction;
an emitter contact with an upper end connected to the emitter electrode and a lower end connected to a portion between the region directly below the gate wiring and the second portion in the semiconductor portion.

2. The semiconductor device according to claim 1, wherein the emitter contact is disposed between the gate electrode and the gate wiring when viewed from above.

3. The semiconductor device according to claim 2, wherein the gate electrode is provided in plurality along the second direction, and the emitter contact is also disposed between the portions of the gate electrode in the semiconductor portion and the gate wiring when viewed from above.

4. The semiconductor device according to claim 1, wherein a plurality of emitter contacts are provided and arranged along the second direction.

5. The semiconductor device according to claim 1, wherein the length of the emitter contact in the second direction is longer than the length of the emitter contact in the first direction.

6. The semiconductor device according to claim 1, further comprising:
a first trench electrode disposed in the semiconductor portion and connected to the emitter electrode, arranged between the gate electrodes in the second direction;
a first plug with an upper end connected to the emitter electrode and a lower end connected to a portion between the gate electrode and the first trench electrode in the semiconductor portion.

7. The semiconductor device according to claim 6, further comprising:
a second trench electrode disposed between the two first portions belonging to one gate electrode in the semiconductor portion and connected to the emitter electrode;
a second plug with an upper end connected to the emitter electrode and a lower end connected to a portion between the gate electrode and the second trench electrode in the semiconductor portion.

8. The semiconductor device according to claim 1, wherein the semiconductor portion comprises:
a p-type first semiconductor layer connected to the collector electrode;
an n-type second semiconductor layer disposed on the first semiconductor layer;
a p-type third semiconductor layer disposed on the second semiconductor layer and connected to the emitter contact;
an n-type fourth semiconductor layer disposed on a part of the third semiconductor layer, facing the first portion via a gate insulating film, and connected to the emitter electrode.
